(19) United States
(12) Patent Application Publication
(10) Pub. No.: US 2025/0038100 A1
(43) Pub. Date: Jan. 30, 2025

(54) SEMICONDUCTOR PACKAGE AND METHOD OF MANUFACTURING THE SEMICONDUCTOR PACKAGE

(71) Applicant: Samsung Electronics Co., Ltd., Suwon-si (KR)

(72) Inventor: Daehun Lee, Suwon-si (KR)

(21) Appl. No.: 18/659,430

(22) Filed: May 9, 2024

(30) Foreign Application Priority Data
Jul. 27, 2023 (KR) 10-2023-0098369

(51) Int. Cl. H01L 23/498; H01L 23/28; H01L 25/10

(52) U.S. Cl. CPC H01L 23/49894; H01L 23/28; H01L 23/49811; H01L 25/105

(57) ABSTRACT

A semiconductor package includes a package substrate including a first region and a second region surrounding the first region, the package substrate including a first insulation layer on an upper surface, an outermost insulation layer on the first insulation layer of the package substrate, the outermost insulation layer defining a window that exposes the first region of the package substrate, a first electronic device on the first region of the package substrate, an underfill member in the window of the outermost insulation layer on the first region of the package substrate, the underfill member at least partially filling a gap between the first electronic device and the package substrate, and a second electronic device on the outermost insulation layer.

### PRIORITY STATEMENT

This application claims priority under 35 U.S.C. § 119 to Korean Patent Application No. 10-2023-0098369, filed on Jul. 27, 2023 in the Korean Intellectual Property Office (KIPO), the contents of which are herein incorporated by reference in their entirety.

### BACKGROUND

Example embodiments relate to a semiconductor package and a method of manufacturing the semiconductor package. More particularly, example embodiments relate to a semiconductor package including a plurality of different chips stacked on a package substrate and a manufacturing method thereof.

Instead of Package on Package (POP), Core-System-in-Package (Core-SIP) where a System on Chip (SOC) and a memory device such as DRAM mounted side by side may be applied. However, in Core-SIP, a relatively large horizontal area may be required to mount DRAM and SOC on a board. Additionally, a difference in coefficients of thermal expansion of components of the package may be large. Thus, at an area where SOC is mounted, warpage may increase in a crying or upwardly convex direction in which both ends hang downward compared to a middle area, and, at an edge area of the package, warpage may increase in a smile or downwardly convex direction in which the middle area hang downward compared to the both ends.

### SUMMARY

Example embodiments provide a semiconductor package having a structure capable of preventing a warpage of the package and reducing a size of the package.

Example embodiments provide a method of manufacturing the semiconductor package.

According to example embodiments, a semiconductor package includes a package substrate including a first region and a second region surrounding the first region, the package substrate including a first insulation layer on an upper surface thereof, an outermost insulation layer on the first insulation layer of the package substrate, the outermost insulation layer defining a window that exposes the first region of the package substrate, a first electronic device on the first region of the package substrate, an underfill member in the window of the outermost insulation layer on the first region of the package substrate, the underfill member at least partially filling a gap between the first electronic device and the package substrate and a second electronic device on the outermost insulation layer.

According to example embodiments, a semiconductor package includes a package substrate including a first region and a second region surrounding the first region, the package substrate including a first insulation layer on an upper surface thereof, the first insulation layer exposing a plurality of first substrate pads in the first region and a plurality of second substrate pads in the second region; an outermost insulation layer on the first insulation layer of the package substrate, the outermost insulation layer including a window that exposes the first region of the package substrate, the outermost insulation layer including a plurality of third substrate pads that are electrically connected to the plurality of second substrate pads, respectively; a first electronic device on the first region of the package substrate; a plurality of first conductive connection members between the package substrate and the first electronic device, a plurality of first conductive connection members electrically connecting the plurality of first substrate pads and the first electronic device; an underfill member in the window of the outermost insulation layer on the first region of the package substrate, the underfill member at least partially filling a gap between the first electronic device and the package substrate; and a second electronic device on the outermost insulation layer.

According to example embodiments, a semiconductor package includes a package substrate including a first region and a second region surrounding the first region, the package substrate including a first insulation layer on an upper surface thereof, an outermost insulation layer on the first insulation layer of the package substrate, the outermost insulation layer including a window that exposes the first region of the package substrate; a first electronic device on the first region of the package substrate; an underfill member in the window of the outermost insulation layer on the first region of the package substrate and at least partially filling a gap between the first electronic device and the package substrate; and a second electronic device on the outermost insulation layer, wherein the window of the outermost insulation layer includes a first inner surface, a second inner surface, a third inner surface and a fourth inner surface, and the first to fourth inner surfaces surround the first region, wherein a thickness of the first insulation layer is smaller than a thickness of the outermost insulation layer, wherein a first coefficient of thermal expansion of the first insulation layer and a second coefficient of thermal expansion of the outermost insulation layer are greater than a third coefficient of thermal expansion of the package substrate.

According to example embodiments, a semiconductor package includes a package substrate having a first region and a second region surrounding the first region and providing a first insulation layer on an upper surface of the package substrate, an outermost insulation layer stacked on the first insulation layer and having a window exposing the first region, a first electronic device mounted on the first region of the package substrate, an underfill member provided within the window on the first region of the package substrate and filling a gap between the first electronic device and the package substrate and a second electronic device mounted on the outermost insulation layer.

The underfill member may be disposed within the window of the outermost insulation layer. The window of the outermost insulation layer may serve as a stiffener and a dam to prevent bleeding of underfill on the first region of the package substrate. Further, the window of the outermost insulation layer may reduce a difference in coefficient of thermal expansion of the package.

Accordingly, an overall size of the semiconductor package may be reduced because the semiconductor package does not require an additional dam to prevent bleeding of underfill.

Additionally, the difference in the coefficient of thermal expansion of the package may be reduced. And, a modulus of elasticity of the package may be secured. Thus, warpage of the package may be reduced in a crying or upwardly convex direction, where both ends hang downward compared to a middle area at a region where the SOC is mounted.

### BRIEF DESCRIPTION OF THE DRAWINGS

FIG. 1 is a plan view illustrating a semiconductor package in accordance with example embodiments.

FIG. 2 is a cross-sectional view taken along the line A-A′ in FIG. 1.

FIG. 3 is a plan view illustrating a package substrate of the semiconductor package in FIG. 1.

FIG. 4 is a cross-sectional view taken along the line B-B′ in FIG. 3.

FIG. 5 is a plan view illustrating a package substrate providing an outermost insulation layer in the semiconductor package in FIG. 1.

FIG. 6 is a cross-sectional view taken along the line C-C′ in FIG. 5.

FIGS. 7 to 14 are views illustrating a method of manufacturing a semiconductor package in accordance with example embodiments.

### DETAILED DESCRIPTION

Hereinafter, example embodiments will be explained in detail with reference to the accompanying drawings.

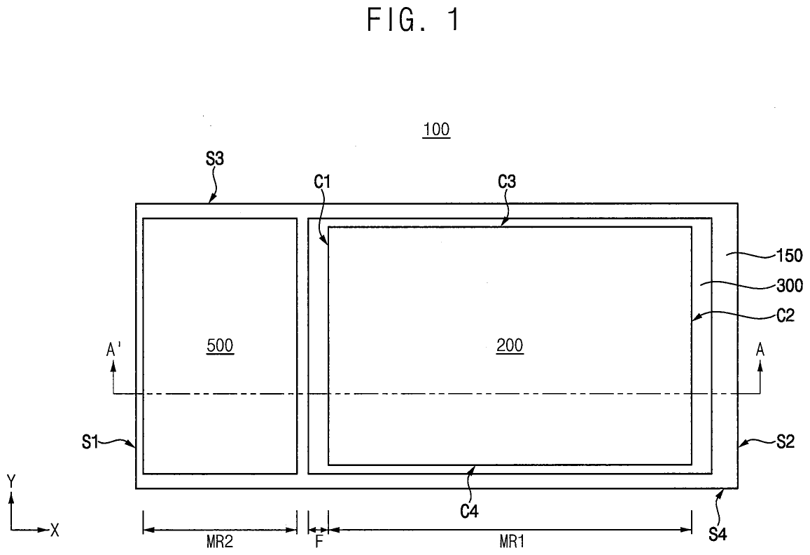

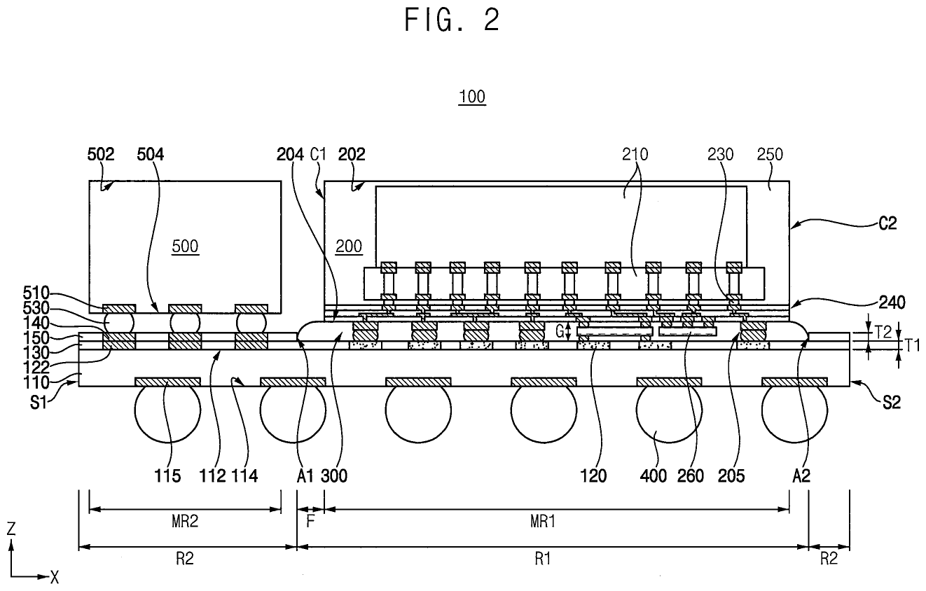

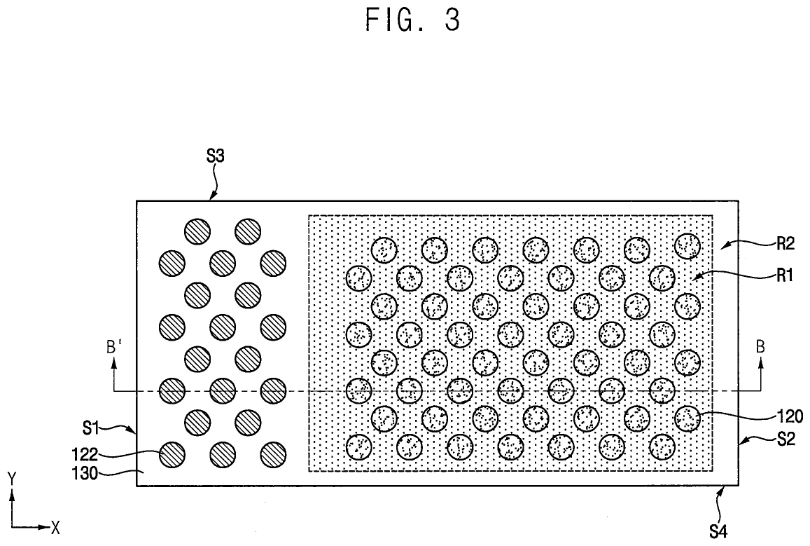

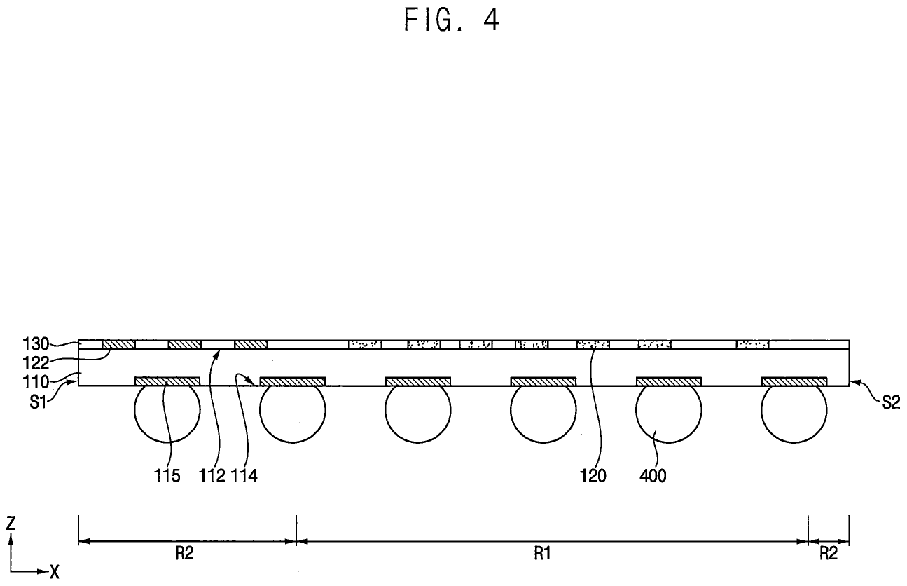

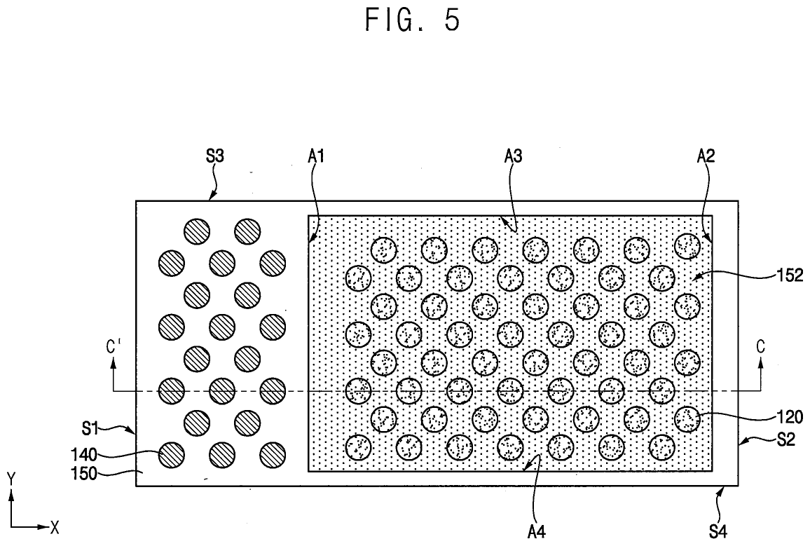

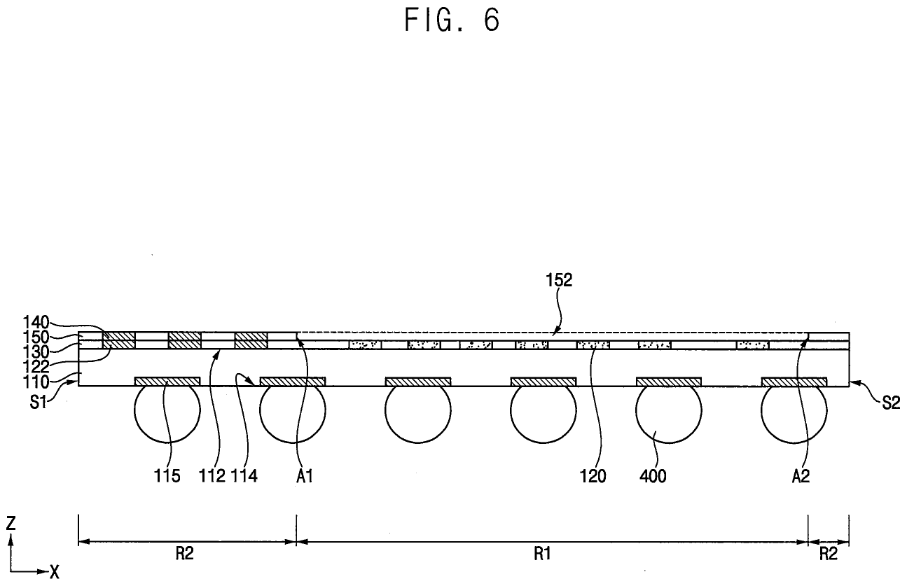

FIG. 1 is a plan view illustrating a semiconductor package in accordance with example embodiments. FIG. 2 is a cross-sectional view taken along the line A-A′ in FIG. 1. FIG. 3 is a plan view illustrating a package substrate of the semiconductor package in FIG. 1. FIG. 4 is a cross-sectional view taken along the line B-B′ in FIG. 3. FIG. 5 is a plan view illustrating a package substrate providing an outermost insulation layer in the semiconductor package in FIG. 1. FIG. 6 is a cross-sectional view taken along the line C-C′ in FIG. 5.

Referring to FIGS. 1 to 6, a semiconductor package 100 may include may include a package substrate 110, a first electronic device 200, an underfill member 300 and a second electronic device 500. The first electronic device 200 may include a first semiconductor chip 210 and a redistribution wiring layer 240. The semiconductor package 100 may further include an external connection member 400 and a first conductive connection member 205 electrically connecting the package substrate 110 and the first electronic device 200. Additionally, the first electronic device 200 may further include a second conductive connection member 230 electrically connecting the first semiconductor chip 210 and the redistribution wiring layer 240.

Further, the semiconductor package 100 may include a third conductive connection member 530 electrically connecting the second electronic device 500 and the package substrate 110.

In example embodiments, the package substrate 110 may be a substrate having an upper surface 112 and a lower surface 114 opposite to each other. For example, the package substrate 110 may include a printed circuit board, a flexible board, a tape board, or the like. The printed circuit board may be a multilayer circuit board having vias and various circuits therein. The package substrate 110 may include internal wires as channels for electrical connection between the first electronic device 200 and the second electronic device 500.

The package substrate 110 may include a first side or first side portion S1 and a second side or second side portion S2 extending in a second direction (Y direction) perpendicular to the upper surface 112 to face each other and a third side or third side portion S3 and a fourth side or fourth side portion S4 extending in a first direction (X direction) to face each other. The first to fourth side portions may be perpendicular to an upper surface 112 of the package substrate 110.

The package substrate 110 may have a first region R1 adjacent to the second side portion S2 and a second region R2 surrounding the first region R1. As illustrated in FIG. 3, the first region R1 may have a rectangular shape. The package substrate 110 may have a first mounting region MR1. The first mounting region MR1 may be provided in the first region R1 of the package substrate 110. The first mounting region MR1 may have a rectangular shape.

The package substrate 110 may include a plurality of first substrate pads 120 arranged in the first mounting region MR1 and a plurality of second substrate pads 122 arranged in the second region R2. The second substrate pads 122 may be disposed in a region adjacent to the first side portion S1 of the package substrate 110. The first substrate pads 120 and the second substrate pads 122 may be connected to the wirings, respectively. The wires may extend from the upper surface 112 or inside of the package substrate 110. For example, at least a portion of the wiring may be used as the substrate pad as a landing pad.

The package substrate 110 may include a first insulation layer 130. The first insulation layer 130 may be disposed on the upper surface 112 of the package substrate 110 to expose the first and second substrate pads 120 and 122. The first insulation layer 130 may cover an entire upper surface 112 of the package substrate 110 except for the first and second substrate pads 120 and 122. For example, the first insulation layer may include a solder resist.

A plurality of third substrate pads 140 may be disposed on the first insulation layer 130. The plurality of third substrate pads 140 may be provided in a region adjacent to the first side portion S1 of the package substrate 110. The plurality of third substrate pads 140 may be electrically connected to the plurality of first substrate pads 120, respectively. The plurality of third substrate pads 140 may be in contact with the plurality of second substrate pads 122, respectively.

A second or outermost insulation layer 150 may be disposed on an upper surface of the first insulation layer 130 to expose the plurality of third substrate pads 140. The outermost insulation layer 150 may be formed on the package substrate 110 to cover the entire second region R2 of the package substrate 110 except for the plurality of third substrate pads 140. For example, the outermost insulation layer may include a solder resist.

In the second region R2 of the package substrate 110, a plurality of insulation layers may be provided such that the first insulation layer 130 and the outermost insulation layer 150 may be sequentially stacked. Accordingly, the outermost insulation layer 150 may be added to serve as a stiffener to reduce warpage of the package substrate 110.

The outermost insulation layer 150 may be provided on the package substrate 110 to surround a circumference of the first region R1 of the package substrate 110. As illustrated in FIGS. 5 and 6, the outermost insulation layer 150 may have a window or opening 152 that exposes the first region R1 of the package substrate 110. The window 152 of the outermost insulation layer 150 may have first and second inner side surfaces A1 and A2 extending in the second direction (Y direction) to face each other and third and fourth inner side surfaces A3 and A4 extending in the first direction (X direction) to face each other. The window 152 of the outermost insulation layer 150 may be formed to surround the circumference of the first region R1 of the package substrate 110. That is, a lower surface of the window 152 of the outermost insulation layer 150 may be overlapped with the first region R1 of the package substrate 110, and the window 152 may be a receiving groove having an open rectangular shape.

The outermost insulation layer 150 may have a second mounting region MR2 adjacent to the first side portion S1. The second mounting region MR2 may have a rectangular shape. The plurality of third substrate pads 140 may be provided in the second mounting region MR2 of the outermost insulation layer 150.

In example embodiments, a second thickness T2 of the outermost insulation layer 150 may be greater than a first thickness T1 of the first insulation layer 130. For example, the first thickness T1 of the first insulation layer 130 may be within the range of 8 μm to 12 μm. The second thickness T2 of the outermost insulation layer 150 may be within a range of 15 μm to 18 μm.

The first insulation layer 130 may have a first thermal expansion coefficient CTE 1, and the outermost insulation layer 150 may have a second thermal expansion coefficient CTE 2, and the package substrate 110 may have a third thermal expansion coefficient CTE 3. For example, the first thermal expansion coefficient CTE 1 and the second thermal expansion coefficient CTE 2 may be greater than the third thermal expansion coefficient CTE 3.

Additionally, the first thermal expansion coefficient CTE 1 and the second thermal expansion coefficient CTE 2 may be the same. The first thermal expansion coefficient CTE 1 of the first insulation layer 130 and the second thermal expansion coefficient CTE 2 of the outermost insulation layer 150 may be within a range of 35 ppm/° C. to 45 ppm/° C.

Although some substrate pads are illustrated, the number, shapes and locations of the substrate pads are illustrated as an example, and thus, it may not be limited thereto. Since the wirings as well as the substrate pads are well known in the art to which the present inventive concept pertains, illustration and further detailed description concerning these elements will be omitted in the interest of brevity.

In example embodiments, a plurality of lower substrate pads 115 may be disposed on the lower surface 114 of the package substrate 110. The plurality of lower substrate pads 115 may be arranged in an array along the first direction (X direction) and the second direction (Y direction). The plurality of lower substrate pads 115 may be disposed to be exposed from the lower surface 114 of the package substrate 110. The plurality of lower substrate pads 115 may be connected to the wires, respectively. The wires may extend from the lower surface 114 or the inside of the package substrate 110.

In example embodiments, the first electronic device 200 may be mounted on the first mounting region MR1 of the package substrate 110. For example, the first electronic device 200 may include a system on chip (SOC).

The first electronic device 200 may be mounted on the package substrate 110 via the first conductive connection member 205. In a plan view, the first electronic device 200 may have a square or rectangular shape. For example, the first electronic device 200 may have a rectangular parallelepiped shape having four side surfaces. The first electronic device 200 may have a first outer or side surface C1 adjacent to the second mounting region MR2 of the package substrate 110, a second outer or side surface C2 facing the first outer surface C1, a third outer or side surface C3 adjacent to the third side portion S3 of the package substrate 110 and a fourth outer or side surface C4 facing the third outer surface C3.

As illustrated in FIG. 2, the first electronic device 200 may have an upper surface 202 and a lower surface 204, and the first electronic device 200 may be mounted on the package substrate 110 such that the lower surface 204 of the first electronic device 200 faces the package substrate 110.

The first electronic device 200 may be disposed in the window 152 of the outermost insulating layer 150. In a plan view, the first electronic device 200 may be mounted to be spaced apart from the outermost insulating layer 150 by a predetermined distance F. For example, the distance F between the first outer surface C1 of the first electronic device 200 and the first inner surface A1 of the outermost insulation layer 150 may be at least 100 m.

The first electronic device 200 may be electrically connected to the first substrate pads 120 of the package substrate 110 via conductive bumps as the first conductive connection members 205, for example, solder bumps. A gap G may be formed between the upper surface 112 of the package substrate 110 and the lower surface 204 of the first electronic device 200 by conductive bumps 205.

In example embodiments, the first electronic device 200 may include at least one first semiconductor chip 210, a redistribution wiring layer 240 and a sealing member 250. For example, the first semiconductor chip 210 may be a logic chip including a logic circuit. For example, the first semiconductor chip 210 may be a system on a chip (SOC) that a chip includes major semiconductor devices such as an operation device (CPU), a memory device (DRAM, flash, etc.), and a digital signal processing device (DSP) so that the chip itself becomes a system. That is, the first semiconductor chip 210 may be a processor chip such as an application processor (AP).

In example embodiments, the first semiconductor chip 210 may have a three-dimensional integrated circuit (3D-IC) structure in which a system on a chip SOC is separated and stacked. For example, the first semiconductor chip 210 may have a plurality of through vias therein. The first semiconductor chip 210 may be electrically connected through the plurality of through via. For example, the through via may be a through silicon via (TSV).

A redistribution wiring layer 240 may be disposed under the first semiconductor chip 210. The redistribution wiring layer 240 may be electrically connected to the first semiconductor chip 210 through the second conductive connection member 230. The redistribution wiring layer 240 may be electrically connected to the plurality of first substrate pads 120 of the package substrate 110 via the plurality of first conductive connection members 205, respectively.

The sealing member 250 may be formed on the redistribution wiring layer 240 to cover the first semiconductor chip 210. The sealing member may include a thermosetting resin, for example, an epoxy mold compound (EMC).

In example embodiments, a plurality of electrical devices 260 may be provided in the gap G between the upper surface 112 of the package substrate 110 and the lower surface 204 of the first electronic device 200. The plurality of electrical devices 260 may be electrically connected to the first electronic device 200 via conductive bumps. For example, the electric device 260 may include at least one capacitor. For example, the at least one capacitor may be provided to improve electrical characteristics of the first electronic device 200.

The size, arrangement, and structure of the first electronic device 200 are shown as an example, and it can be understood that the present inventive concept is not limited thereto. In addition, only a few chip pads and electronic devices are illustrated in the drawings, but the structure, shape, and arrangement of the chip pads and electronic devices above are provided as an example, and it can be understood that the present inventive concept is not limited thereto.

In example embodiments, the underfill member 300 may be underfilled between the first electronic device 200 and the package substrate 110. The underfill member 300 may fill the gap G provided between the upper surface 112 of the package substrate 110 and the lower surface 204 of the first electronic device 200. The underfill member 300 may be disposed in the window 152 of the outermost insulating layer 150. The underfill member 300 covers or surrounds the first conductive connection members 205. Accordingly, the underfill member 300 may strengthen the connection between the first electronic device 200 and the package substrate 110.

The underfill member 300 may include a material with relatively high fluidity to effectively charge or fill a small space between the first electronic device 200 and the package substrate 110. For example, the underfill member 300 may include an adhesive including an epoxy material.

The underfill member 300 may have a fourth thermal expansion coefficient CTE 4. For example, the fourth thermal expansion coefficient CTE 4 may be smaller than the thermal expansion coefficient CTE 1 of the first insulating layer 130 and the thermal expansion coefficient CTE 2 of the outermost insulation layer 150. The fourth thermal expansion coefficient CTE 4 of the underfill member 300 may be within a range of 4 ppm/° C. to 7 ppm/° C.

For example, an upper portion or surface of the underfill member 300 may be in contact with the lower surface 204 of the first electronic device, and a lower portion or surface of the underfill member 300 may be in contact with the first insulation layer 130 of the package substrate 110. Side portions or surfaces of the underfill member 300 may be in contact with the first inner surface A1, the second inner surface A2, the third inner surface A3, and the fourth inner surface A4 of the outermost insulating layer 150. The underfill member 300 may be disposed in the window 152 of the outermost insulation layer 150. Accordingly, the first inner surface A1, the second inner surface A2, the third inner surface A3, and the fourth inner surface A4 of the window 152 of the outermost insulation layer 150 may serve as an underfill dam.

In example embodiments, a plurality of external connection members 400 may be provided on the lower surface 114 of the package substrate 110. The plurality of external connection members 400 may be disposed on the plurality of lower substrate pads 115 exposed from the lower surface 114 of the package substrate 110, respectively. Each of the plurality of external connection members 400 may be arranged as an array along the first direction (X direction) and the second direction (Y direction) in contact with the plurality of lower substrate pads 115. Each of the plurality of external connection members 400 may be electrically connected to the plurality of lower substrate pads 115.

In example embodiments, the second electronic device 500 may be mounted on the second mounting region MR2 of the outermost insulation layer 150. The second electronic device 500 may be mounted on the outermost insulation layer 150 via a plurality of third conductive connection members 530. The second electronic device 500 may be disposed such that a lower surface 504 on which a plurality of chip pads 510 are formed, that is, the active surface faces the package substrate 110. In a plan view, the second electronic device 500 may have a square or rectangular shape having four side surfaces. The plurality of chip pads 510 may be arranged as an array along the entire lower surface 504 of the second electronic device 500.

The second electronic device 500 may be a semiconductor package including at least one semiconductor chip. The at least one semiconductor chip may be a memory chip including a memory circuit. For example, the second electronic device 500 may include a volatile memory device such as a DRAM device.

The plurality of chip pads 510 of the second electronic device 500 may be electrically connected to the plurality of third substrate pads 140 of the outermost insulation layer 150 via conductive bumps as the plurality of third conductive connection members 530, for example, solder bumps.

The size and arrangement of the second electronic device 500 are shown as an example, and it may be understood that the present inventive concept is not limited thereto. Also, only a few chip pads are illustrated in the drawings, but the structure, shape, and arrangement of the chip pads above are provided as an example, and it can be understood that the present inventive concept is not limited thereto.

As mentioned above, the semiconductor package includes the package substrate 110 having the first region R1 and the second region R2 surrounding the first region R1, the outermost insulation layer 150 stacked on the second region R2 of the package substrate 110 and having the window 152 that exposes the first region R1, the first electronic device 200 mounted on the first region R1 of the package substrate 110, the underfill member 300 provided within the window 152 on the first region R1 of the package substrate 110 and filling the gap G between the first electronic device 200 and the package substrate 110 and the second electronic device 500 mounted on the outermost insulation layer 150.

The underfill member 300 may be disposed within the window 152 of the outermost insulation layer 150. The window 152 of the outermost insulation layer 150 may serve as a stiffener and a dam to prevent bleeding of underfill on the first region R1 of the package substrate 110. Further, the window 152 of the outermost insulation layer 150 may reduce a difference in coefficient of thermal expansion of the package.

Accordingly, an overall size of the semiconductor package may be reduced because the semiconductor package does not require an additional dam to prevent bleeding of underfill. Additionally, the difference in the coefficient of thermal expansion of the package may be reduced. Further, a modulus of elasticity of the package may be secured. Thus, warpage of the package may be reduced in a crying or upwardly convex direction, where both ends are hang downward compared to a middle area at a region where the SOC is mounted

Hereinafter, a method of manufacturing the semiconductor package of FIG. 1 will be described.

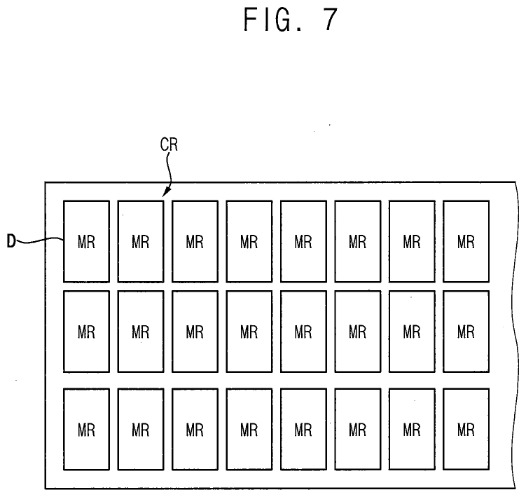

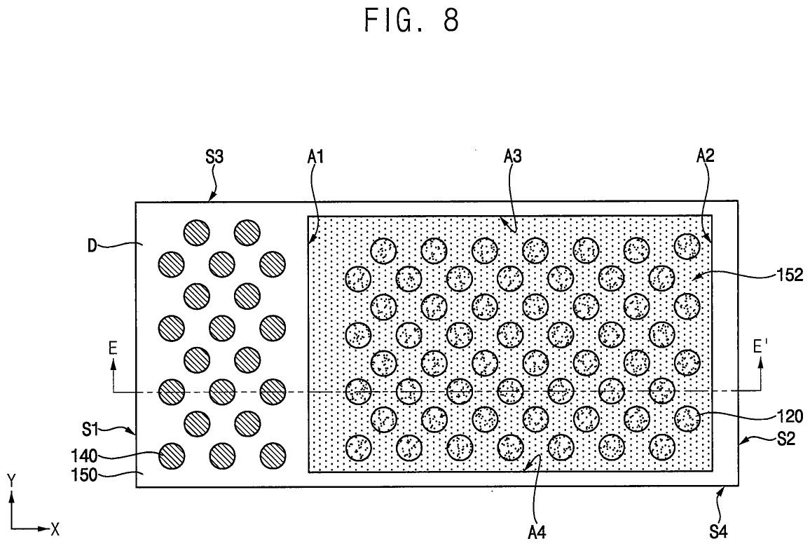

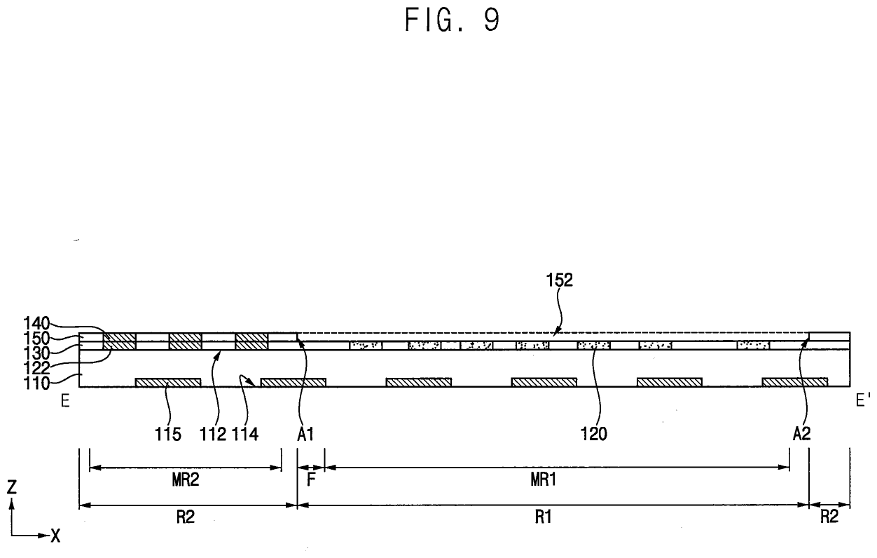

FIGS. 7 to 14 are views illustrating a method of manufacturing a semiconductor package in accordance with example embodiments. FIG. 8 is an enlarged plan view illustrating portion ‘D’ in FIG. 7. FIG. 9 is a cross-sectional view taken along the line E-E′ in FIG. 8.

Referring to FIGS. 7 to 9, a package substrate 110 having an outermost insulating layer 150 may be provided.

As illustrated in FIG. 7, a substrate strip in which a plurality of package substrates are arranged in a plurality of rows may be provided. The substrate strip may include a mounting region MR for mounting electronic devices and a cutting region CR surrounding the mounting region MR. As will be described below, the substrate strip may be cut along the cutting region CR dividing the mounting area MR to be individualized.

In example embodiments, a package substrate 110 may be a substrate having an upper surface 112 and a lower surface 114 to opposite to each other. For example, the package substrate 110 may include a printed circuit board, a flexible board, a tape board, or the like. The printed circuit board may be a multilayer circuit board having a via and various circuits therein. The package substrate 110 may include internal wires as channels for electrical connection between the first electronic device 200 and the second electronic device 500.

The package substrate 110 may include a first side portion S1 and a second side portion S2 extending in a second direction (Y direction) perpendicular to the upper surface 112 to face each other and a third side portion S3 and a fourth side portion S4 extending in a first direction (X direction) to face each other. The first to fourth side portions may be perpendicular to an upper surface 112 of the package substrate 110.

The package substrate 110 may have a first region R1 adjacent to the second side portion S2 and a second region R2 surrounding the first region R1. As illustrated in FIG. 8, the first region R1 may have a rectangular shape. The package substrate 110 may have a first mounting region MR1. The first mounting region MR1 may be provided in the first region R1 of the package substrate 110. The first mounting region MR1 may have a rectangular shape.

The package substrate 110 may include a plurality of first substrate pads 120 arranged in the first region R1 and a plurality of second substrate pads 122 arranged in the second region R2. The second substrate pads 122 may be disposed in a region adjacent to the first side portion S1 of the package substrate 110. The first substrate pads 120 and the second substrate pads 122 may be connected to the wirings, respectively. The wires may extend from the upper surface 112 or inside of the package substrate 110. For example, at least a portion of the wiring may be used as the substrate pad as a landing pad.

The package substrate 110 may include a first insulation layer 130. The first insulation layer 130 may be disposed on the upper surface 112 of the package substrate 110 to expose the first and second substrate pads 120 and 122. The first insulation layer 130 may cover an entire upper surface 112 of the package substrate 110 except for the first and second substrate pads 120 and 122. For example, the first insulation layer may include a solder resist.

A plurality of third substrate pads 140 may be disposed on the first insulation layer 130. The plurality of third substrate pads 140 may be provided in a region adjacent to the first side portion S1 of the package substrate 110. The plurality of third substrate pads 140 may be electrically connected to the plurality of first substrate pads 120, respectively. The plurality of third substrate pads 140 may be in contact with the plurality of second substrate pads 122, respectively.

An outermost insulation layer 150 may be disposed on the package substrate 110 to expose the plurality of third substrate pads 140. The outermost insulation layer 150 may be formed on the package substrate 110 to cover the entire second region R2 of the package substrate 110 except for the plurality of third substrate pads 140. For example, the outermost insulation layer may include a solder resist.

In the second region R2 of the package substrate 110, a plurality of insulation layers may be provided such that the first insulation layer 130 and the outermost insulation layer 150 may be sequentially stacked. Accordingly, the outermost insulation layer 150 may be added to serve as a stiffener to reduce warpage of the package substrate 110.

The outermost insulation layer 150 may be provided on the package substrate 110 to surround a circumference of the first region R1 of the package substrate 110. As illustrated in FIGS. 5 and 6, the outermost insulation layer 150 may have a window 152 that exposes the first region R1 of the package substrate 110. The window 152 of the outermost insulation layer 150 may have first and second inner side surfaces A1 and A2 extending along the second direction (Y direction) to face each other and third and fourth inner side surfaces A3 and A4 extending along the first direction (X direction) to face each other. The window 152 of the outermost insulation layer 150 may be formed to surround the circumference of the first region R1 of the package substrate 110. That is, a lower surface of the window 152 of the outermost insulation layer 150 may be overlapped with the first region R1 of the package substrate 110, and the window 152 may be a receiving groove having an open rectangular shape.

The outermost insulation layer 150 may have a second mounting region MR2 adjacent to the first side portion S1. The second mounting region MR2 may have a rectangular shape. The plurality of third substrate pads 140 may be provided in the second mounting region MR2 of the outermost insulation layer 150.

In example embodiments, a second thickness T2 of the outermost insulation layer 150 may be greater than a first thickness T1 of the first insulation layer 130. For example, the first thickness T1 of the first insulation layer 130 may be within the range of 8 μm to 12 μm. The second thickness T2 of the outermost insulation layer 150 may be within a range of 15 μm to 18 μm.

The first insulation layer 130 may have a first thermal expansion coefficient CTE 1, and the outermost insulation layer 150 may have a second thermal expansion coefficient CTE 2, and the package substrate 110 may have a third thermal expansion coefficient CTE 3. For example, the first thermal expansion coefficient CTE1 and the second thermal expansion coefficient CTE2 may be greater than the third thermal expansion coefficient CTE3.

Additionally, the first thermal expansion coefficient CTE1 and the second thermal expansion coefficient CTE2 may be the same. The first thermal expansion coefficient CTE1 of the first insulation layer 130 and the second thermal expansion coefficient CTE2 of the outermost insulation layer 150 may be within a range of 35 ppm/° C. to 45 ppm/° C.

Although some substrate pads are illustrated, the number, shapes and locations of the substrate pads are illustrated as an example, and thus, it may not be limited thereto. Since the wirings as well as the substrate pads are well known in the art to which the present inventive concept pertains, illustration and further detailed description concerning these elements will be omitted in the interest of brevity.

In example embodiments, a plurality of lower substrate pads 115 may be disposed on the lower surface 114 of the package substrate 110. The plurality of lower substrate pads 115 may be arranged in an array along the first direction (X direction) and the second direction (Y direction). The plurality of lower substrate pads 115 may be disposed to be exposed from the lower surface 114 of the package substrate 110. The plurality of lower substrate pads 115 may be connected to the wires, respectively. The wires may extend from the lower surface 114 or the inside of the package substrate 110.

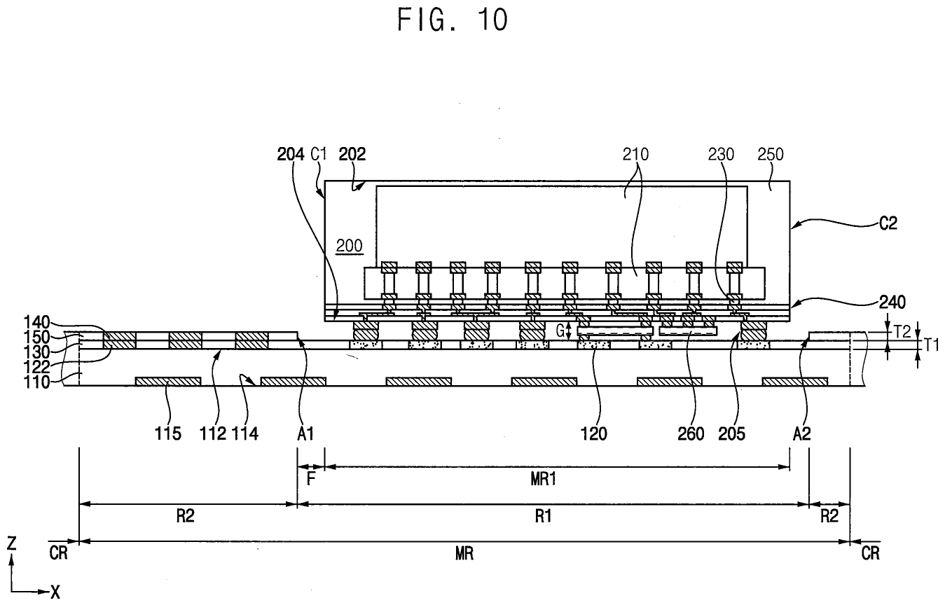

Referring to FIGS. 10, a first electronic device 200 may be mounted on the first mounting region MR1 of the package substrate 110. For example, the first electronic device 200 may include a system on chip (SOC). The first electronic device 200 may have an upper surface 202 and a lower surface 204, and the first electronic device 200 may be mounted on the package substrate 110 such that the lower surface 204 of the first electronic device 200 faces the package substrate 110.

The first electronic device 200 may be mounted on the package substrate 110 via the first conductive connection member 205. In a plan view, the first electronic device 200 may have a square or rectangular shape. For example, the first electronic device 200 may have a rectangular parallelepiped shape having four side surfaces. The first electronic device 200 may have a first outer surface C1 adjacent to the second mounting region MR2 of the package substrate 110, a second outer surface C2 facing the first outer surface C1, a third outer surface C3 adjacent to the third side portion S3 of the package substrate 110 and a fourth outer surface C4 facing the third outer surface C3.

The first electronic device 200 may be disposed in the window 152 of the outermost insulating layer 150. In a plan view, the first electronic device 200 may be mounted to be spaced apart from the outermost insulating layer 150 by a predetermined distance F. For example, the distance F between the first outer surface C1 of the first electronic device 200 and the first inner surface A1 of the outermost insulation layer 150 may be at least 100 m.

The first electronic device 200 may be electrically connected to the first substrate pads 120 of the package substrate 110 via conductive bumps as the first conductive connection members 205, for example, solder bumps. A gap G may be formed between the upper surface 112 of the package substrate 110 and the lower surface 204 of the first electronic device 200 by conductive bumps 205.

In example embodiments, the first electronic device 200 may include at least one first semiconductor chip 210, a redistribution wiring layer 240 and a sealing member 250.

For example, the first semiconductor chip 210 may be a logic chip including a logic circuit. For example, the first semiconductor chip 210 may be a system on a chip (SOC) that a chip includes major semiconductor devices such as an operation device (CPU), a memory device (DRAM, flash, etc.), and a digital signal processing device (DSP) so that the chip itself becomes a system. That is, the first semiconductor chip 210 may be a processor chip such as an application processor (AP).

In example embodiments, the first semiconductor chip 210 may have a three-dimensional integrated circuit (3D-IC) structure in which a system on a chip SOC is separated and stacked. For example, the first semiconductor chip 210 may have a plurality of through vias therein. The first semiconductor chip 210 may be electrically connected through the plurality of through via. For example, the through via may be a through silicon via (TSV).

A redistribution wiring layer 240 may be disposed under the first semiconductor chip 210. The redistribution wiring layer 240 may be electrically connected to the first semiconductor chip 210 through the second conductive connection member 230. The redistribution wiring layer 240 may be electrically connected to the plurality of first substrate pads 120 of the package substrate 110 via the plurality of first conductive connection members 205, respectively.

The sealing member 250 may be formed on the redistribution wiring layer 240 to cover the first semiconductor chip 210. The sealing member may include a thermosetting resin, for example, an epoxy mold compound (EMC).

In example embodiments, a plurality of electrical devices 260 may be provided in the gap G between the upper surface 112 of the package substrate 110 and the lower surface 204 of the first electronic device 200. The plurality of electrical devices 260 may be electrically connected to the first electronic device 200 via conductive bumps. For example, the electric device 260 may include at least one capacitor. For example, the at least one capacitor may be provided to improve electrical characteristics of the first electronic device 200.

The size, arrangement, and structure of the first electronic device 200 are shown as an example, and it can be understood that the present inventive concept is not limited thereto. In addition, only a few chip pads and electronic devices are illustrated in the drawings, but the structure, shape, and arrangement of the chip pads and electronic devices above are provided as an example, and it can be understood that the present inventive concept is not limited thereto.

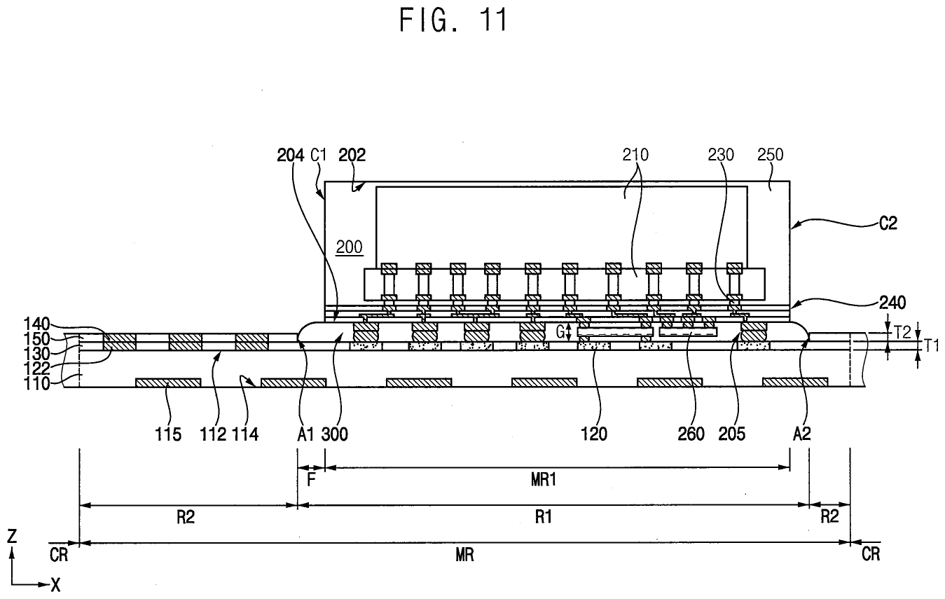

Referring to FIG. 11, an underfill member 300 may be formed between the first electronic device 200 and the package substrate 110.

For example, while moving a dispenser nozzle along one side of the first electronic device 200, an underfill solution may be dispensed between the first electronic device 200 and the first insulation layer 130, and the underfill solution may be cured to form the underfill member 300. The underfill solution may flow through the gap G arranged between the upper surface 112 of the package substrate 110 and the lower surface 204 of the first electronic device 200 and then be cured to form the underfill member 300. The underfill member 300 may be disposed in the window 152 of the outermost insulation layer 150. The underfill member 300 covers or surrounds the first conductive connection members 205. Accordingly, the underfill member 300 may strengthen the connection between the first electronic device 200 and the package substrate 110.

The underfill member 300 may include a material with relatively high fluidity to effectively charge or fill a small space between the first electronic device 200 and the package substrate 110. For example, the underfill member 300 may include an adhesive including an epoxy material.

The underfill member 300 may have a fourth thermal expansion coefficient CTE 4.

For example, the fourth thermal expansion coefficient CTE 4 may be smaller than the thermal expansion coefficient CTE 1 of the first insulation layer 130 and the thermal expansion coefficient CTE 2 of the outermost insulation layer 150. For example, the fourth thermal expansion coefficient CTE 4 of the underfill member 300 may be within a range of 4 ppm/° C. to 7 ppm/° C.

For example, an upper portion of the underfill member 300 may be in contact with the lower surface 204 of the first electronic device 200, and a lower portion of the underfill member 300 may be contact with the first insulation layer 130 of the package substrate 110. Side portions of the underfill member 300 may be in contact with the first inner surface A1, the second inner surface A2, the third inner surface A3, and the fourth inner surface A4 of the window 152 of the outermost insulation layer 150. The flow of the underfill solution may be controlled by the first inner surface A1, the second inner surface A2, the third inner surface A3, and the fourth inner surface A4 of the window 152 of the outermost insulation layer 150. Accordingly, the first inner surface A1, the second inner surface A2, the third inner surface A3, and the fourth inner surface A4 of the outermost insulation layer 150 may serve as an underfill dam.

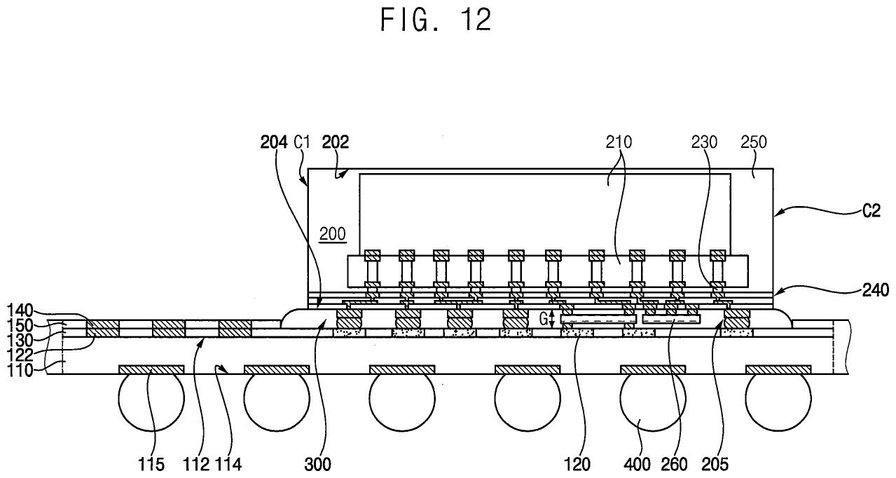

Referring to FIG. 12, a plurality of external connection members 400 may be attached to the plurality of lower substrate pads 115 provided on the lower surface 114 of the package substrate 110.

In example embodiments, the plurality of external connection members 400 may be disposed on the plurality of lower substrate pads 115 exposed from the lower surface 114 of the package substrate 110, respectively. Each of the plurality of external connection members 400 may be arranged as an array along the first direction (X direction) and the second direction (Y direction) to be in contact with the plurality of lower substrate pads 115. Each of the plurality of external connection members 400 may be electrically connected to the plurality of lower substrate pads 115.

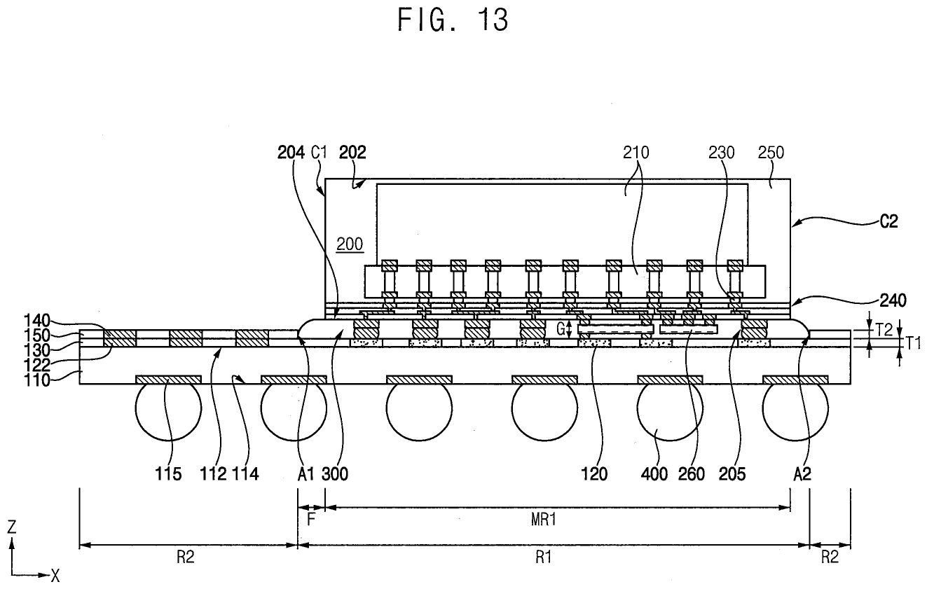

Referring to FIG. 13, the substrate strip may be cut along the cutting region CR to form an individual package including the first electronic device 200 and the external connection members 400. A blade process may be performed to cut the substrate strip and to divide the substrate strip into individual packages.

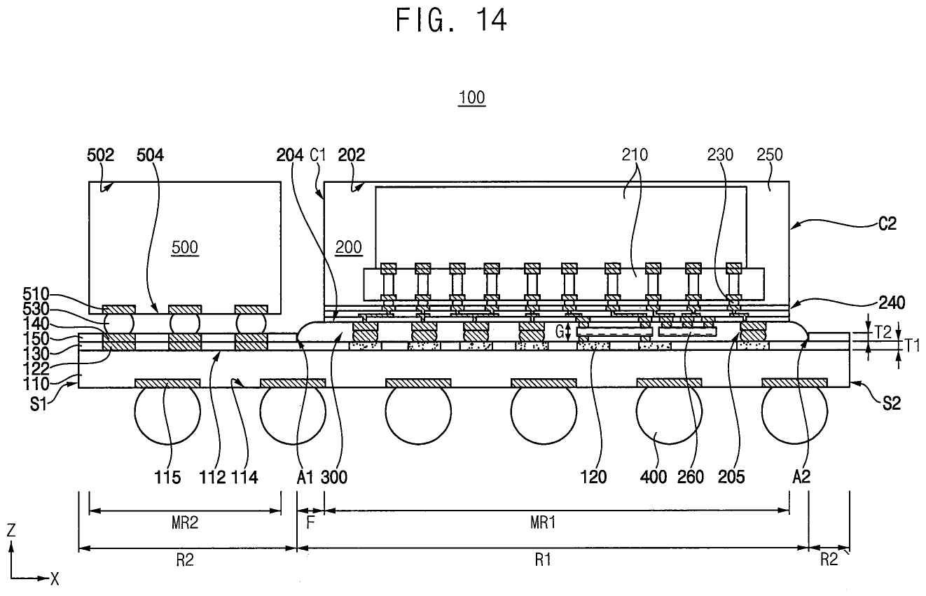

Referring to FIG. 14, a second electronic device 500 may have an upper surface 502 and a lower surface 504, and a second electronic device 500 may be mounted such that the lower surface 504 of the second electronic device 500 faces the package substrate 110.

The second electronic device 500 may be mounted on the second mounting region MR2 of the outermost insulation layer 150. The second electronic device 500 may be mounted on the outermost insulation layer 150 via a plurality of third conductive connection members 530. The second electronic device 500 may be disposed such that a lower surface 504 on which a plurality of chip pads 510 are formed, that is, the active surface faces the package substrate 110. In a plan view, the second electronic device 500 may have a square or rectangular shape having four side surfaces. The plurality of chip pads 510 may be arranged as an array along the entire lower surface 504 of the second electronic device 500.

The second electronic device 500 may be a semiconductor package including at least one semiconductor chip. The at least one semiconductor chip may be a memory chip including a memory circuit. For example, the second electronic device 500 may include a volatile memory device such as a DRAM device.

The plurality of chip pads 510 of the second electronic device 500 may be electrically connected to the plurality of third substrate pads 140 of the outermost insulation layer 150 via conductive bumps as the plurality of third conductive connection members 530, for example, solder bumps.

The size and arrangement of the second electronic device 500 are shown as an example, and it may be understood that the present inventive concept is not limited thereto. Also, only a few chip pads are illustrated in the drawings, but the structure, shape, and arrangement of the chip pads above are provided as an example, and it can be understood that the present inventive concept is not limited thereto.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present inventive concept. Accordingly, all such modifications are intended to be included within the scope of inventive concept as defined in the claims.

What is claimed is:

1. A semiconductor package, comprising:
a package substrate including a first region and a second region surrounding the first region, the package substrate including a first insulation layer on an upper surface thereof;
an outermost insulation layer on the first insulation layer of the package substrate, the outermost insulation layer defining a window that exposes the first region of the package substrate;
a first electronic device on the first region of the package substrate;
an underfill member in the window of the outermost insulation layer on the first region of the package substrate, the underfill member at least partially filling a gap between the first electronic device and the package substrate; and
a second electronic device on the outermost insulation layer.

2. The semiconductor package of claim 1, wherein the window of the outermost insulation layer includes a first inner surface, a second inner surface, a third inner surface and a fourth inner surface, and the first to fourth inner surfaces surround the first region.

3. The semiconductor package of claim 1, wherein a distance between a side surface of the first electronic device and an inner surface of the window of the outermost insulation layer is at least 100 μm.

4. The semiconductor package of claim 1, wherein a thickness of the first insulation layer is smaller than a thickness of the outermost insulation layer.

5. The semiconductor package of claim 4, wherein the thickness of the first insulation layer is within a range of 8 μm to 12 μm, and the thickness of the outermost insulation layer is within a range of 15 μm to 18 μm.

6. The semiconductor package of claim 1, wherein the first insulation layer has a first coefficient of thermal expansion, the outermost insulation layer has a second coefficient of thermal expansion, and the package substrate has a third coefficient of thermal expansion,
wherein the first coefficient of thermal expansion and the second coefficient of thermal expansion are greater than the third coefficient of thermal expansion.

7. The semiconductor package of claim 6, wherein the first coefficient of thermal expansion and the second coefficient of thermal expansion are within a range of 35 ppm/° C. to 45 ppm/° C.

8. The semiconductor package of claim 6, wherein the underfill member has a fourth coefficient of thermal expansion,
and the first coefficient of thermal expansion and the second coefficient of thermal expansion are greater than the fourth coefficient of thermal expansion.

9. The semiconductor package of claim 8, wherein the fourth coefficient of thermal expansion is within a range of 4 ppm/° C. to 7 ppm/° C.

10. The semiconductor package of claim 1, further comprising:
a plurality of external connection members respectively on a plurality of lower substrate pads on a lower surface of the package substrate.

11. A semiconductor package, comprising:
a package substrate including a first region and a second region surrounding the first region, the package substrate including a first insulation layer on an upper surface thereof, the first insulation layer exposing a plurality of first substrate pads in the first region and a plurality of second substrate pads in the second region;
an outermost insulation layer on the first insulation layer of the package substrate, the outermost insulation layer including a window that exposes the first region of the package substrate, the outermost insulation layer including a plurality of third substrate pads that are electrically connected to the plurality of second substrate pads, respectively;
a first electronic device on the first region of the package substrate;
a plurality of first conductive connection members between the package substrate and the first electronic device, the plurality of first conductive connection members electrically connecting the plurality of first substrate pads and the first electronic device;
an underfill member in the window of the outermost insulation layer on the first region of the package substrate, the underfill member at least partially filling a gap between the first electronic device and the package substrate; and
a second electronic device on the outermost insulation layer.

12. The semiconductor package of claim 11, wherein the window of the outermost insulation layer includes a first inner surface, a second inner surface, a third inner surface and a fourth inner surface, and the first to fourth inner surfaces surround the first region.

13. The semiconductor package of claim 11, wherein a distance between a side surface of the first electronic device and an inner surface of the window of the outermost insulation layer is at least 100 μm.

14. The semiconductor package of claim 11, wherein a thickness of the first insulation layer is smaller than a thickness of the outermost insulation layer.

15. The semiconductor package of claim 14, wherein the thickness of the first insulation layer is within a range of 8 μm to 12 μm, and the thickness of the outermost insulation layer is within a range of 15 μm to 18 μm.

16. The semiconductor package of claim 11, wherein the first insulation layer has a first coefficient of thermal expansion, and the outermost insulation layer has a second coefficient of thermal expansion, and the package substrate has a third coefficient of thermal expansion,
wherein the first coefficient of thermal expansion and the second coefficient of thermal expansion are greater than the third coefficient of thermal expansion.

17. The semiconductor package of claim 16, wherein the first coefficient of thermal expansion and the second coefficient of thermal expansion are within a range of 35 ppm/° C. to 45 ppm/° C.

18. The semiconductor package of claim 17, wherein the underfill member has a fourth coefficient of thermal expansion,
and the first coefficient of thermal expansion and the second coefficient of thermal expansion are greater than the fourth coefficient of thermal expansion.

19. The semiconductor package of claim 11, further comprising:
a plurality of external connection members respectively on a plurality of lower substrate pads on a lower surface of the package substrate.

20. A semiconductor package, comprising:
a package substrate including a first region and a second region surrounding the first region, the package substrate including a first insulation layer on an upper surface thereof;
an outermost insulation layer on the first insulation layer of the package substrate, the outermost insulation layer including a window that exposes the first region of the package substrate;
a first electronic device on the first region of the package substrate;
an underfill member in the window of the outermost insulation layer on the first region of the package substrate and at least partially filling a gap between the first electronic device and the package substrate; and
a second electronic device on the outermost insulation layer,
wherein the window of the outermost insulation layer includes a first inner surface, a second inner surface, a third inner surface and a fourth inner surface, and the first to fourth inner surfaces surround the first region,
wherein a thickness of the first insulation layer is smaller than a thickness of the outermost insulation layer,
wherein a first coefficient of thermal expansion of the first insulation layer and a second coefficient of thermal expansion of the outermost insulation layer are greater than a third coefficient of thermal expansion of the package substrate.
